(19) United States
(12) Patent Application Publication
(10) Pub. No.: US 2026/0328822 A1
(43) Pub. Date: Oct. 22, 2026

(54) MICROWAVE-PHOTONIC HYBRID DEVICES FOR MEASURING MICROWAVE FREQUENCY VARIATION BASED ON INTERFEROMETRIC SINE-COSINE SENSING AND PHOTONIC DELAY-LINE

(71) Applicant: Xiaotian Steve Yao, Las Vegas, NV (US)

(72) Inventor: Xiaotian Steve Yao, Las Vegas, NV (US)

(21) Appl. No.: 19/651,435

(22) Filed: Apr. 17, 2026

Related U.S. Application Data
(60) Provisional application No. 63/790,663, filed on Apr. 17, 2025.

(51) Int. Cl. G01R 29/08

(52) U.S. Cl. CPC G01R 29/0878

(57) ABSTRACT

The disclosed technology implements two microwave or radio frequency (RF) interferometers in which the delay imbalance in the first interferometer is configured to be one quarter wavelength longer than that of the second interferometer to produce an additional phase difference between the two arms. The two outputs of each of the first and second interferometers are then detected by two detectors to produce two complementary interference signals. The difference between the two complementary interference signals of the first interferometer is a sine function of the signal frequency while the difference between the two complementary interference signals of the second interferometer is proportional to a cosine function of the signal frequency. The sine/cosine relationships with the signal frequency allow for measuring variations in the signal frequency by integrating a photonic delay line and microwave/RF to optical conversion to achieve real-time measurement of the frequency variation.

### PRIORITY CLAIM AND CROSS-REFERENCE TO RELATED APPLICATION(S)

This patent document claims the priority of and benefits of U.S. Provisional Patent Application No. 63/790,663 entitled “Title: MICROWAVE-PHOTONIC HYBRID DEVICES FOR MEASURING MICROWAVE FREQUENCY VARIATION BASED ON INTERFEROMETRIC SINE-COSINE SENSING AND PHOTONIC DELAY-LINE” filed Apr. 17, 2025.

### TECHNICAL FIELD

This patent document relates to microwave frequency devices capable of measuring microwave frequency variations.

### BACKGROUND

Many applications involve determining the frequency information of microwave signals, especially, measurement of the microwave signal frequency information with a high accuracy, at a high spectral resolution and at a high speed.

### SUMMARY

The technology disclosed in this patent document implements two microwave or radio frequency (RF) interferometers as two arms of a microwave or radio frequency measurement device in which the delay imbalance in the first interferometer is configured to be one quarter wavelength longer than that of the second interferometer to produce an additional phase difference between the two arms. The two outputs of each of the first and second interferometers are then detected by two microwave or RF detectors to produce two complementary interference signals. The difference between the two complementary interference signals of the first interferometer is a sine function of the microwave or RF frequency while the difference between the two complementary interference signals of the second interferometer is proportional to a cosine function of the microwave or RF frequency. Using the sine/cosine interpretation algorithm allow for measuring variations in the microwave or RF frequency with a high spectral resolution by using the above interferometer design in combination with a photonic delay line and microwave/RF to optical conversion to achieve real-time microwave or RF frequency variation measurement for a wide range of applications.

The disclosed technology leverages the sine-cosine encoder principle, enabled by a photonic delay line (PhDL), to detect rapid microwave or RF frequency variations in real time with an ultra-high spectral resolution, and at fast speeds to measure signal frequencies in a wide frequency range. Thie disclosed technology can be implemented to accurately characterize microwave or RF frequency variation parameters of a tunable signal source, including the chirp rate, tuning direction, waveform, range, tuning ripples, and nonlinearity. The advancements provided by the disclosed technology can be used for detecting microwave or RF frequency variations with unprecedented high spectral resolution and dynamic range, and can be highly valuable in various applications including secure communications, passive Doppler radar systems, electronic warfare, metrology, and scientific research.

### BRIEF DESCRIPTION OF DRAWINGS

FIG. 1 shows an example of a simplified schematic diagram of one implementation the disclosed sine-cosine radio frequency detection or microwave frequency detection (MFD) measurement scheme. FIG. 1(a): The input signal to be tested; FIG. 1(b): The upper unbalanced I-Q interferometer for high spectral resolution detection of microwave frequency variations (MFVs); FIG. 1(c): The lower unbalanced interferometer for absolute frequency estimation; FIG. 1(d): The output signal waveforms from the upper interferometer in response to the frequency swept input signal; FIG. 1(e) The demodulated phase from the obtained sine and cosine waves; FIG. 1(f) The unwrapped phase and the corresponding MFV detected; FIG. 1(g) The output from the lower interferometer and the demodulated phase representing MFV. Δω=2πΔf: the angular frequency variation, SUT: signal under test, PS: power splitter, MVA: manual variable attenuator, 90° HC: 90-degree hybrid coupler, MD: microwave Detector.

FIG. 2 shows an example of a system diagram of a photonic delay line (PhDL) enabled sine-cosine MFD device. FIG. 2(a): Schematic of the experimental setup. FIG. 2(b) Photo of the experimental setup. PhDL: photonic delay-line, SUT: signal under test, PS1, PS2, PS3, PS4: power splitter, MVA: manual variable attenuator, 90° hybrid coupler HCl, 90° hybrid coupler HC2, 90° hybrid coupler HC3, 90° hybrid coupler HC4: , MD: microwave Detector, DML: directly modulated laser, SMF: single mode fiber coil (1 km), PD: photodetector, LNA: microwave low noise amplifiers, VA: Voltage amplifier, DAQ: data acquisition card, PC: computer.

FIG. 3 shows an example of PhDL enabled sine-cosine MFD frequency sweep characterization. FIG. 3(a): The measured frequency variations from a signal source (Keysight N5242A) in a range from 5.7 to 12.7 GHZ (AF: absolute frequency). FIG. 3(b) Frequency sweep rate obtained by time-differentiating the data in (a). FIG. 3(c) Linear fit (green) of the first sweep cycle in (a) and the deviations from the fit (red). FIG. 3(d) Deviations from the linear fits of three cycles in (a). FIGS. 3(e), (f), and (g): Enlarged views from the green boxes in (a), showing the internal frequency scan correction process of the signal source.

FIG. 4 shows an example of Frequency resolution characterization of PhDL enabled sine-cosine MFD. FIGS. 4(a)-(c): examples of measured frequency variations of stepped frequency scans with step increments of 500 Hz, 100 Hz, and 50 Hz (Orange: measurement result, light blue: numerical simulation). FIGS. 4(d)-(f): Measured frequency hops with magnitudes of 500 Hz, 100 Hz, and 50 Hz.

FIG. 5 shows examples of measurement speed characterization of our PhDL enabled sine-cosine MFD. FIG. 5(a): Frequency sweeps measured using a DAQ card of 80 kSa/s (AF: absolute frequency). FIG. 5(b): The frequency-sweeping rate obtained by time-differentiating the data in FIG. 5(a). FIG. 5(c) Frequency sweeps measured using a high-speed oscilloscope of 625 MSa/s for data acquisition. FIG. 5(d) The frequency-sweeping rate obtained by time-differentiating the data in FIG. 5(c).

FIG. 6 shows examples of frequency resolution comparison: short-time FFT vs. sine-cosine MFD. FIGS. 6(a)-(c) MFV measured using the short-time Fourier transform (ST-FFT) module of a RSA306B for frequency hopping magnitudes of 50 Hz, 100 Hz, and 1 kHz, respectively. FIGS. 6(d)-(f): MFV measured using our sine-cosine MFD for frequency hopping magnitudes of 50 Hz, 100 Hz, and 1 kHz, respectively.

FIG. 7 shows an example of an experimental setup for generating and detecting Doppler frequency shift using our sine-cosine MFD system. RFS: radio frequency source, DDS: direct digital synthesizer, VCPS: voltage-controlled phase shifter.

FIG. 8 shows an examples of measurements for showing Doppler shift generation and detection. FIGS. 8(a) and (b): triangular-wave and quadratic-wave signals generated by the DDS, respectively, for modulating the VCPS to generate Doppler shifts. FIGS. 8(c) and (d): Measured (blue) and simulated (green) Doppler shifts corresponding to the triangular- and quadratic-wave driving signals, respectively.

FIG. 9 shows examples of measurements indicating the characterization of rapid frequency sweeps from a FDML OEO. FIGS. 9(a) and (b): The MFV of four periods of frequency-swept signal from a FDML-OEO measured with our sine-cosine MFD and a commercial real-time spectrum analyzer (Keysight UXR0134A), respectively. FIG. 9(c): Linear fit of the middle segment (red) in the first cycle of (a), with the blue curve representing the measured value and the red line being the linear fit. FIG. 9(d): Frequency-sweep rate of the FDML-OEO derived from the time derivative of data in FIG. 9(c). FIGS. 9(e) and (f): Detailed frequency variations at the beginning and ending segments, respectively, of a frequency-sweeping cycle in the dotted boxes of FIG. 9(a).

### DETAILED DESCRIPTION

Real-time detection of RF frequency variations or microwave frequency variations (MFVs) can be important in various devices, systems or applications, including, for example, Doppler radar [1], biomedicine [2], microwave sensing [3], and aerospace [1]. MFV detection (MFD) has traditionally been direct detection via a spectrum analyzer which requires considerable cost. However, the measurements by a spectrum analyzer may be disadvantageously subject to a trade-off among its detection range, speed, and resolution [4]. Moreover, various implementation of direct detection through a spectrum analyzer may be limited to providing the frequency and power information of the unknown signal without obtaining the time-frequency information [5, 6]. To understand how the frequency of a microwave signal changes over time, it is necessary to use time-frequency analysis equipment or alternative technologies [2, 6, 7]. Some existing time-frequency analysis devices, such as high-end spectrum analyzers with waterfall chart functions and real-time spectrum analyzers based on short-time Fourier transforms, are not only expensive and bulky but also often limited in detection speed, accuracy, and range due to the performance of analog-to-digital converters and digital signal processors [8, 9]. The time-frequency analysis bandwidth of various existing time-frequency analysis devices may be typically restricted to only tens to hundreds of MHz [1].

With the increasing convergence of microwave and optical technologies, there has been a significant proliferation of research endeavors focusing on microwave frequency detection methodologies that capitalize on the principles of microwave photonics. These microwave photonics-assisted measurement technologies have the potential to outperform traditional direct electrical detection methods, providing numerous advantages based on the use of optical components and optical devices operated in the optical domain, including broader bandwidth, smaller size, lighter weight, lower signal loss, and enhanced resistance to interference [10]. The predominant microwave photonics-based frequency measurement techniques currently in vogue include approaches of frequency-power mapping [11], frequency-time mapping [12], four-wave mixing [13], and that harnesses the phenomenon of stimulated Brillouin scattering [14].

Frequency-power mapping MFD schemes entail translating microwave frequency fluctuations into power variations of microwave or optical waves. The central tenet is to forge a functional relationship that links known microwave signal frequency shifts to detector voltage fluctuations, thereby obtaining the MFV of the measured signal from the observed voltage changes [11, 15-18]. The foremost merit of this technology is its extensive detection range; however, it is marred by relatively subpar testing resolution, typically at the MHz level [15]. Frequency-time mapping MFD method first converts the measured microwave signal into an optical signal with only upper and lower sidebands through an electro-optic modulator [12, 19-25]. Then, a high-speed optical switch is used to transform the optical signals of the upper and lower sidebands into a single optical pulse. The optical pulse, after passing through a highly dispersive medium, broadens, thereby increasing its duration [19], which is related to the frequency of the measured microwave signal. Although this detection technique can encompass a broad frequency spectrum, its resolution is generally compromised due to the limited dispersion of the dispersive medium [22, 23]. Four-wave mixing techniques also offer promise for broad-band microwave frequency measurements [13, 26-28]. However, this technique requires at least two laser sources with known wavelengths, and the wavelength stability of these light sources significantly impacts the accuracy of the measured frequency. Consequently, it falls short for applications demanding high MFV resolution. Although stimulated Brillouin scattering of optical signals can be used to achieve microwave frequency resolution at the MHz level, this detection technique requires the use of a microwave signal source with an equivalent testing bandwidth, thereby increasing the cost of the testing technique [14, 29-33].

The sine-cosine frequency detection technology was recently developed to use optical interferometry for detecting optical frequency variations (OFVs) [34-36], primarily targeting the measurement of rapid optical frequency variations with ultra-high resolution and the assessment of rapidly tunable or low-frequency jitter lasers. Such sine-cosine frequency detection technology based on optical interferometry revolves around representing the phase difference between the two interfering arms as sine and cosine functions to compute the OFV information after the light beam goes through an unbalanced interferometer. The longer the signal path delay (OPD) between the two arms, the higher the achievable measurement. This mirrors the sine-cosine encoder concept employed to glean motor rotation information [37], enabling the concurrent attainment of high frequency resolution and a wide frequency range without mutual encumbrances. Examples and technical details for devices based on optical interferometry for detecting optical frequency variations (OFVs) can be found i US Patent Application Publication No. US 2023-0236295 A1 entitled “Sine-cosine optical frequency detection devices for photonics integrated circuits and applications in lidar and other distributed optical sensing” which is which is part of the disclosure of this patent document.

The microwave-photonic hybrid devices for measuring microwave frequency variations combines an optical delay line and the concept of the sine-cosine optical frequency detection (OFD) to provide the real-time measurement of MFVs. Such a sine-cosine microwave frequency detector (MFD) may be achieved by converting a microwave signal in one of the two arms of a unbalanced microwave interferometer into a modulated optical signal through a long photonic delay line (PhDL) (e.g., 1 km long in some designs) and subsequently converting the delayed optical signal back to the microwave domain to cause a long phase delay between the microwave signals of the two arms of the unbalanced microwave interferometer. This use of the optical delay line can be used to achieve a sufficiently large delay in the microwave domain that is difficult to achieve using conventional microwave delay components (such as coaxial cables) with significant signal loss.

Prototype microwave-photonic hybrid devices for measuring microwave frequency variations were constructed and tested to achieve a frequency resolution of 50 Hz, a detection speed of 1 THz/s, and a measurement frequency range of 7 GHz from 5.7 to 12.7 GHZ. All the MFV parameters, including the MFV speed, range, direction, ripples, and nonlinearity can be accurately characterized. A comparative study was conducted to compare a prototype microwave-photonic hybrid device and a commercial short-time Fourier analyzer from Tektronix (RSA306B). The results clearly showed that the disclosed microwave-photonic hybrid device outperforms the commercial analyzer in both resolution and measurement range in MFV measurements.

In addition, the disclosed microwave or radio frequency photonic hybrid device was tested for detecting minute Doppler frequency shifts from modulating a phase shifter and a large chirp microwave frequency sweep generated by a Fourier domain mode-locked (FDML) optoelectronic oscillator (OEO) (a Fourier domain mode-locked optoelectronic oscillator or FDML-OEO) and the results are in excellent agreement with theoretical computations. The measurement results of the FDML OEO also indicate the sine-cosine MFD is capable of detecting MFV speed up to an impressive 63 THz/s. As shown in Table 1, the MFV resolution of the disclosed sine-cosine MFD is significantly improved over the previously described microwave photonics-based frequency measurement techniques, by at least 4 orders of magnitude, making it attractive for a wide range of applications requiring high frequency resolution over a wide frequency range.

TABLE 1
Comparison of Different MFV Measurement Techniques

| Ref. | Method | Range (GHz) | Resolution (Hz) | |
|---|---|---|---|---|
| [11] | Frequency-power | 0~13.8 | ≤±300 | MHz |
| [15] | mapping | 4.4~8.7 | ≤±200 | MHz |
| [17] | | 0.5~17.5 | ≤±200 | MHz |
| [18] | | 4~12 | ≤±30 | MHz |
| [12] | Frequency-time | 15~45 | — | |
| [19] | mapping | 0.6~42 | ≤±88 | MHz |
| [21] | | 2~14 | ≤±3 | MHz |
| [23] | | 0~2.43 | 340 | MHz |
| [24] | | 0.6~2.58 | 60 | MHz |
| [25] | | 0.22~23 | 357 | MHz |
| [13] | Four-wave mixing | 1~40 | ≤2 | GHz |
| [26] | | 0~40 | ≤400 | MHz |
| [27] | | 0.04~40 | ≤4.15 | MHz |
| [28] | | 0.01~80 | — | |
| [14] | Stimulated | 0~40 | ≤±10 | MHz |
| [29] | Brillouin | 0~21.42 | ≤±5 | MHz |
| [30] | scattering | 6~18 | ≤±1 | MHz |
| [31] | | 0~12 | 60 | MHz |
| [32] | | 0~4 | 35 | MHz |
| [33] | | 0~12 | 35 | MHz |
| Prototype | photonic delay line | 5.7~12.7 | 50 | Hz |

| | |
|---|---|
| microwave- | (PhDL), enabled |
| photonic | sine-cosine encoder |
| hybrid device | |

The disclosed technology can be implemented to provide a microwave-photonic hybrid device for measuring a variation of a microwave signal frequency which includes a first microwave power splitter to receive and split an input microwave signal at an input microwave frequency into a first input microwave signal and a second input microwave signal; and a photonic module coupled to receive the first input microwave signal from the first microwave power splitter and structured to include: a light source operable to generate light that is modulated by the first input microwave signal to produce a modulated optical signal carrying the first input microwave signal, an optical delay device coupled to receive the modulated optical signal carrying the first input microwave signal and to cause an optical delay in the modulated optical signal, and an optical detector coupled to the optical delay device to convert the modulated optical signal into a photonically delayed first input microwave signal. This microwave-photonic hybrid device includes a first microwave 90-degree hybrid coupler coupled to receive the photonically delayed first input microwave signal from the optical detector of the photonic module to split the received photonically delayed first input microwave signal into a first photonically delayed microwave signal and a second photonically delayed microwave signal that exhibits a 90-degree phase shift relative to a phase of the first photonically delayed microwave signal; a second microwave power splitter coupled to receive and split the second input microwave signal from the first microwave power splitter into a third microwave signal and a fourth microwave signal that exhibits a 90-degree phase shift relative to a phase of the third microwave signal; and a second microwave 90-degree hybrid coupler coupled to receive the first photonically delayed microwave signal from the first microwave 90-degree hybrid coupler and the third microwave signal from the second microwave power splitter to form a first microwave Mach-Zehnder interferometer to cause interference between the first photonically delayed microwave signal and the third microwave signal to produce first and second microwave Mach-Zehnder interferometer output signals.

In addition, this microwave-photonic hybrid device includes a first microwave detector coupled to receive the first microwave Mach-Zehnder interferometer output signal to produce a first detector output signal; a second microwave detector coupled to receive the second microwave Mach-Zehnder interferometer output signal to produce a second detector output signal; a third microwave 90-degree hybrid coupler coupled to receive the second photonically delayed microwave signal from the first microwave 90-degree hybrid coupler and the fourth microwave signal from the second microwave power splitter to form a second microwave Mach-Zehnder interferometer to cause interference between the second photonically delayed microwave signal and the fourth microwave signal to produce third and fourth microwave Mach-Zehnder interferometer output signals; a third microwave detector coupled to receive the third microwave Mach-Zehnder interferometer output signal to produce a third detector output signal; a fourth microwave detector coupled to receive the fourth microwave Mach-Zehnder interferometer output signal to produce a fourth detector output signal; and a processing module coupled to receive information of the first, second, third and fourth detector output signals and operable to process the first, second, third and fourth detector signals to determine a change in the input microwave frequency of the input microwave signal. As further explained below, in implementing the microwave-photonic hybrid device, the second microwave 90-degree hybrid coupler is configured as the first microwave Mach-Zehnder interferometer to cause each of the first and second microwave Mach-Zehnder interferometer output signals to vary as a sine function of the input microwave frequency of the input microwave signal; and the third microwave 90-degree hybrid coupler is configured as the second microwave Mach-Zehnder interferometer to cause each of the third and fourth microwave Mach-Zehnder interferometer output signals to vary as a cosine function of the input microwave frequency of the input microwave signal.

The specific examples and associated details of such a microwave-photonic hybrid device based on the disclosed technology are provided below.

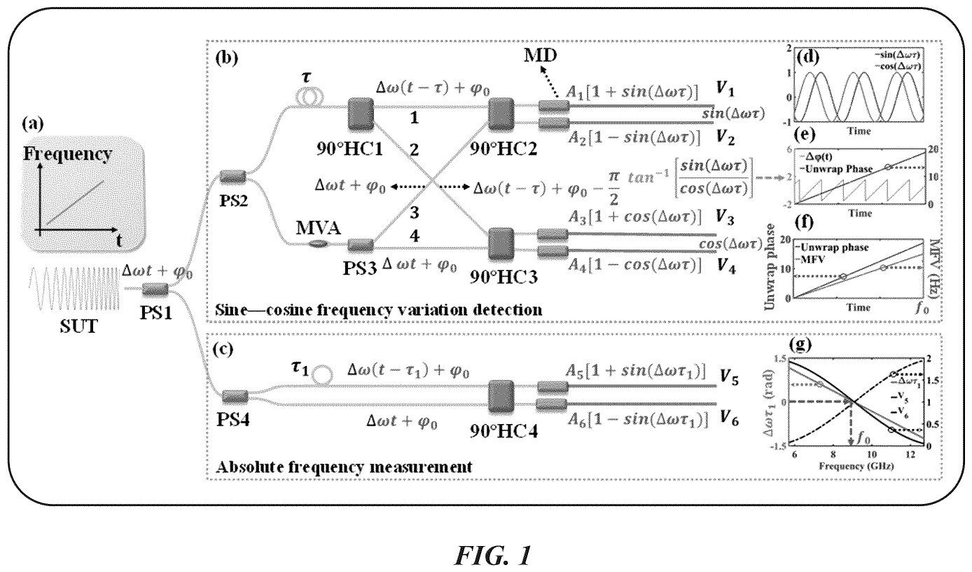

FIG. 1 shows an example of a simplified schematic diagram of a microwave-photonic hybrid device for the sine-cosine MFD measurements. The microwave signal under test (SUT) of FIG. 1(a) enters power splitter PS1 and is evenly divided into two branches: the upper branch signal goes into an unbalanced I-Q interferometer (shown in the blue dashed box labeled (b)) for the accurate determination of the MFVs, and the lower branch signal goes into an unbalanced Mach-Zehnder interferometer (UMZI shown in the red dashed box labeled (c)) for the real-time estimation of absolute frequency. In the I-Q interferometer of the upper branch, the SUT is evenly split into two paths after passing through power splitter PS2. Several 90-degree hybrid couplers are used. The first path signal goes through a long delay t before entering a microwave 90-degree hybrid coupler (90° HCl) which splits an input microwave signal into two output microwave signals with a 90-degree phase shift relative to each other. The second path signal goes through a manual variable attenuator (MVA) before reaching power splitter PS3. The MVA is used to adjust the power entering PS3 to be equal to the power entering the 90° HCl. The two output signals from the 90° HCl are routed through coaxial cables 1 and 2, respectively, before entering 90° HC2 and 90° HC3. One of the output signals from HCl has a phase shift of 90 degrees with respect to the other. The two output signals from PS3 are routed through coaxial cables 3 and 4, respectively, before entering 90° HC2 and 90° HC3. When the coaxial cables 1, 2, 3, and 4 are of equal length, the two output signals from the 90° HC2 are sine signals that are 180° out of phase (the quadrature or Q-channels). In contrast, the two output signals from the 90° HC3 are two cosine signals that are 180° out of phase (the in-phase or I-channels). Finally, the powers of the four output signals are detected by four microwave detectors (MDi, i=1,2,3,4), each followed by a voltage amplifier to convert them into four voltages

$${V}_{1}^{′} , {V}_{2}^{′} , {V}_{3}^{′} and {V}_{4}^{′} .$$

Because MDs are nonlinear, a linearization process is involved in converting them into linearized voltages Vᵢ(t) (i=1,2,3,4). By utilizing two pairs of voltage signals with a 180° phase difference (V₁ vs. V₂, V₃ vs. V₄), a sinusoidal signal and a cosine signal can be obtained, as illustrated in FIG. 1(d). Notably, the arctangent function can be employed to calculate the phase variation Δφ(t) induced by the frequency variation of the signal under test (SUT). The unwrapped phase versus time relationship is subsequently derived through phase unwrapping, as shown in FIG. 1(e). Finally, the corresponding MFV of the SUT can be determined using the formula

$$Δ f ( t ) = \frac{1}{2 π r} Δφ ( t ) ,$$

as depicted in FIG. 1(f).

The detailed process will be thoroughly discussed in the following sections. In the unbalanced Mach-Zehnder interferometer (UMZI) shown in FIG. 1(c), the SUT is evenly split into two paths after passing through PS4. One path enters 90° HC4 through a shorter coaxial cable with a delay τ₁, while the other path enters 90° HC4 directly. The two outputs from 90° HC4 are converted by MD5 and MD6 into two voltages V₅′ and V₆′, which can be amplified and linearized to obtain two sine or cosine signals V₅ and V₆ that are 180 degrees out of phase. If delay τ₁ is chosen to be sufficiently small, V₅ and V₆ can be kept monotonic in the frequency range of interest, as shown in FIG. 1(g), such that the SUT frequency can be uniquely determined from the values of V₅ and V₆, as will be discussed in detail below.

In the example device of FIG. 1, all the microwave components are assumed ideal. However, in practice, due to the component imperfections, the four interference signals Vᵢ (i=1,2,3,4) induced by MFV Δf(t) in FIG. 1(b) can be expressed as:

$${V}_{1} ( t ) = {A}_{1} ( f ) \{ 1 + {k}_{1} sin [ Δφ ( t ) - \frac{α ( f )}{2} ] \} \qquad ( 1 a )$$

$${V}_{2} ( t ) = {A}_{2} ( f ) \{ 1 - {k}_{2} sin [ Δφ ( t ) + \frac{α ( f )}{2} ] \} \qquad ( 1 b )$$

$${V}_{3} ( t ) = {A}_{3} ( f ) \{ 1 + {k}_{3} cos [ Δφ ( t ) + γ ( f ) - \frac{β ( f )}{2} ] \} \qquad ( 1 c )$$

$${V}_{4} ( t ) = {A}_{4} ( f ) \{ 1 - {k}_{4} cos [ Δφ ( t ) + γ ( f ) + \frac{β ( f )}{2} ] \} \qquad ( 1 d )$$

where Δφ(t)=2πτAf(t), Aᵢ (i=1,2,3,4) is the amplitude of the sinusoidal signal of each channel. The signals of such channels are weakly frequency dependent in general, and kᵢ represents the modulation depth in each channel. In Eq. (1), α, β and γ are phase errors introduced by component imperfections, including dispersions in the delay and connecting cables, and phase deviations of the microwave 90-degree hybrid couplers, which are also weakly frequency dependent. Ideally, α, β and γ are all zero. However, as will be seen, even in non-ideal situations, these errors as functions of frequency can be obtained through a calibration procedure and their impacts on the frequency measurement accuracy can be mitigated, as shown below.

By combining Eq. (1a) with Eq. (1b), and Eq. (1c) with Eq. (1d), the following relationship can be derived:

$${V}_{1} ( t ) - \frac{{A}_{1} ( f )}{{A}_{2} ( f )} {V}_{2} ( t ) = {A}_{1} ( f ) {k}_{1} sin [ Δφ ( t ) - \frac{α ( f )}{2} ] + {A}_{1} ( f ) {k}_{2} sin [ Δφ ( t ) + \frac{α ( f )}{2} ] \qquad ( 2 a )$$

$${V}_{3} ( t ) - \frac{{A}_{3} ( f )}{{A}_{4} ( f )} {V}_{4} ( t ) = {A}_{3} ( f ) {k}_{3} cos [ Δφ ( t ) + γ ( f ) - \frac{β ( f )}{2} ] + {A}_{3} ( f ) {k}_{4} cos [ Δφ ( t ) + γ ( f ) + \frac{β ( f )}{2} ] \qquad ( 2 b )$$

Next, a frequency-dependent tangent function can be obtained from Eq. (2a) and Eq. (2b):

$$tan [ Δφ ( t ) ] = \frac{{r}_{14} ( f ) {a}_{1} ( f ) [ {V}_{3} ( t ) - {r}_{34} ( f ) {V}_{4} ( t ) ] - {r}_{34} ( f ) {a}_{2} ( f ) [ {V}_{1} ( t ) - {r}_{12} ( f ) {V}_{2} ( t ) ]}{{r}_{34} ( f ) {a}_{3} ( f ) [ {V}_{1} ( t ) - {r}_{12} ( f ) {V}_{2} ( t ) ] - {r}_{14} ( f ) {a}_{4} ( f ) [ {V}_{3} ( t ) - {r}_{34} ( f ) {V}_{4} ( t ) ]} \qquad ( 3 a )$$

$$where , \\ \{ \begin{matrix}{r}_{ij} ( f ) = \frac{{A}_{i} ( f )}{{A}_{j} ( f )} , ( i , j = 1 , 2 , 3 , 4 ) \\ {a}_{1} ( f ) = ( {k}_{2} - {k}_{1} ) sin \frac{α ( f )}{2} \\ {a}_{2} ( f ) = ( {k}_{3} + {k}_{4} ) cos γ ( f ) cos \frac{β ( f )}{2} + ( {k}_{3} - {k}_{4} ) sin γ ( f ) sin \frac{β ( f )}{2} \\ {a}_{3} ( f ) = - ( {k}_{3} + {k}_{4} ) sin γ ( f ) cos \frac{β ( f )}{2} + ( {k}_{3} - {k}_{4} ) cos γ ( f ) sin \frac{β ( f )}{2} \\ {a}_{4} ( f ) = ( {k}_{1} + {k}_{2} ) cos \frac{α ( f )}{2}\end{matrix} \qquad ( 3 b )$$

Finally, from Eq. (3), the MFV Δf(t) can be expressed as:

$$Δ f ( t ) = \frac{1}{2 π τ} Δφ ( t ) = \frac{1}{2 πτ} {tan}^{- 1} \{ \frac{{r}_{14} {a}_{1} [ {V}_{3} ( t ) - {r}_{34} {V}_{4} ( t ) ] - {r}_{34} {a}_{2} [ {V}_{1} ( t ) - {r}_{12} {V}_{2} ( t ) ]}{{r}_{34} {a}_{3} [ {V}_{1} ( t ) - {r}_{12} {V}_{2} ( t ) ] - {r}_{14} {a}_{4} [ {V}_{3} ( t ) - {r}_{34} {V}_{4} ( t ) ]} \} \qquad ( 4 )$$

Eq. (4) indicates that the system not only can measure the magnitude of the MFV but, more importantly, it can also determine the direction of the microwave signal change. When Δφ(t) increases, it means Δf(t) increases, and vice versa. Since Δφ=2πτΔf, when MFV equals half of the system's free spectral range (FSR=1/τ), Δφ will experience a phase jump of π. By counting the number of jumps n, the measurement range of the system can, in principle, be extended to infinity [34]. However, due to the limited operating bandwidth of the microwave components in the system, the actual measurement range is finite.

Eq. (4) also indicates that as long as the component imperfections α, β, γ, rᵢⱼ and kᵢ can be pre-determined through calibration, their impact on the frequency measurement accuracy can be eliminated. Like the calibration procedure for the sine-cosine optical frequency detector [36], all the frequency dependent parameters at different frequencies can be obtained with a frequency synthesizer and stored in a lookup table of (α, β, γ, rᵢⱼ, kᵢ) vs. f.

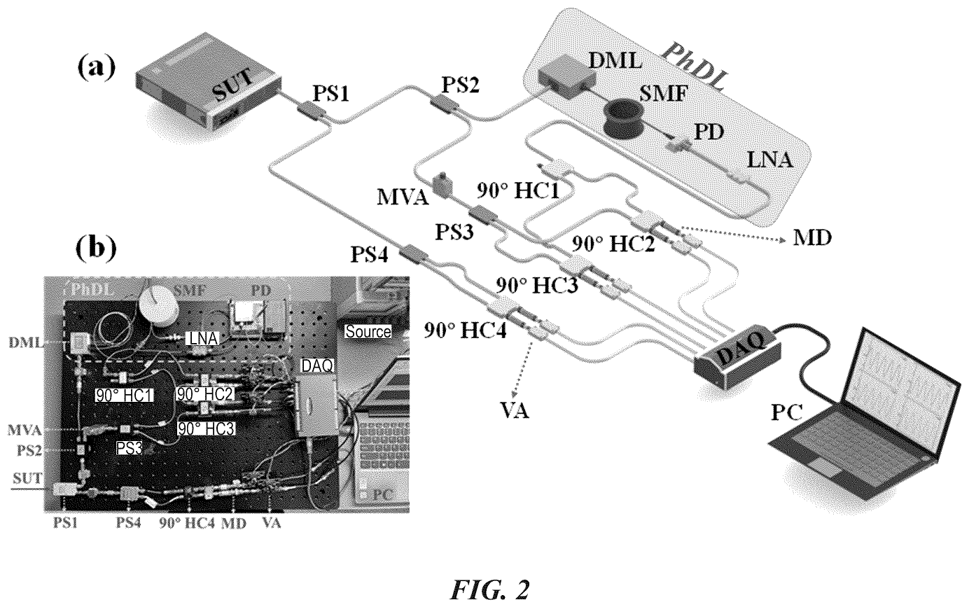

In addition, the frequency resolution is inversely proportional to delay t, again as shown by Eq. (4). Because coax cables are of high transmission loss for high frequency signals, it is advantageous to use a photonic delay line (PhDL), which involves modulating the light from a semiconductor laser with the microwave SUT and have it propagating in a long length of optical fiber before converting back to microwave signal by a photodetector. The laser light can be directly modulated or externally modulated after it goes through an intensity modulator, such as an electro-absorption modulator or a Mach-Zehnder modulator. As will be shown in FIG. 2, a low cost directly modulated PhDL is used in our demonstration.

Due to the periodic nature of the voltages Vᵢ, (i=1,2,3,4), the unbalanced I-Q interferometer with a small free spectral range (FSR) can only be used to measure the incremental frequency change, not the absolute frequency. To circumvent this deficiency, the unbalanced Mach-Zehnder interferometer (UMZI) shown in FIG. 1(c) can be used. Ideally, the output signal of the UMZI as a function of frequency can be expressed as:

V₅(f)=A₅{1+sin[Δφ₁(f)]} (5a)

V₆(f)=A₆{1−sin[Δφ₁(f)]} (5b)

Combining Eq. (5a) and Eq. (5b) leads to:

$${Δφ}_{1} ( f ) = {sin}^{- 1} \frac{{V}_{5} / {A}_{5} - {V}_{5} / {A}_{5}}{{V}_{5} / {A}_{5} + {V}_{5} / {A}_{5}} \qquad ( 6 )$$

By setting delay τ₁ in the UMZI shown in FIG. 1 sufficiently small such that one half of its FSR is larger than the intended measurement range, V₅ and V₆ can be monotonic in the measurement range, which will ensure a unique frequency value can be obtained using Eq. (6). One may use a frequency synthesizer to generate precisely known frequencies to calibrate the output of the UMZI by relating Δφ₁(f) obtained using Eq. (6) with the frequencies from the synthesizer and then store the results of Δφ₁ vs. f in a lookup table. At the start of microwave frequency measurement, the absolute frequency f₀ can be determined once Δφ₁ is calculated from the two outputs of the UMZI. Combining with Eq. (4), the following can be obtained:

f(t)=f₀+Δf(t) (7)

Notably, the lookup table of Δφ₁ vs. f can be used for estimating f for the selection of the frequency dependent parameters in the lookup table of (α, β, γ, rᵢⱼ, kᵢ) vs. f for calculating Δf(t) with Eq. (4).

From Eq. (4), it is evident that the frequency resolution of can be made as small as desirable by increasing the time delay τ. However, an increase in the delay τ results in a decrease in the corresponding FSR of the I-Q interferometer. Consequently, the backend sampling system requires a higher sampling rate. Therefore, with a fixed sampling rate of the acquisition system, a larger delay will lead to a lower detection speed for the sine-cosine MFD system, thereby restricting the maximum detectable MFV rate, represented as γₘₐₓ. Assuming that the voltage acquisition system has a finite sampling rate Rₛ or a sampling period Tₛ, γₘₐₓ can be expressed as [34]:

$${γ}_{max} = \frac{FSR}{2 {T}_{s}} = {R}_{s} * FSR / 2 = {R}_{s} / ( 2 τ ) \qquad ( 8 )$$

Therefore, the maximum allowable delay τₘₐₓ is limited by the intended maximum MFV rate γₘₐₓ by:

τₘₐₓ=Rₛ/(2γₘₐₓ) (9)

Additionally, the frequency resolution of is limited either by the effective resolution of the analog-to-digital converter (ADC) or the noise level of the detection circuit, whichever is larger. Let M represent the effective number of bits of the analog-to-digital converter (ADC), the frequency resolution δf_{ADC} determined by the ADC resolution is [34]:

$$δ {f}_{ADC} = \frac{FSR}{2 \cdot {2}^{M}} = \frac{1}{{2}^{M + 1} \cdot τ} \qquad ( 10 )$$

For example, if the effective resolution of the ADC used in the sine-cosine MFD system is 16 bits and the time delay T is 4.96 ns (corresponding to a signal path delay length of 1.5 m), the frequency resolution δf_{ADC} limited by the ADC resolution is 1.54 kHz.

The noise level of the detection circuit can also limit the system frequency resolution. Let δv represent the voltage noise, and Vₚₚ be the peak-to-peak voltage of the sine and cosine signals. Then, the frequency resolution A foy limited by the noise level of the detection circuit can be expressed as [34]:

$$δ {f}_{n} = \frac{FSR / 2}{{V}_{pp} / {δ}_{v}} = \frac{1}{2 τ {SNR}_{v}} \qquad ( 11 )$$

where SNRᵥ=Vₚₚ/δv is the voltage signal to noise ratio. For example, if τ=4.96 ns in the sine-cosine MFD system, the output of the detection circuit is Vₚₚ=60 mV, and the voltage amplitude noise δv=0.002 mV, the frequency resolution δfₙ limited by the noise level of the detection circuit is 3.36 kHz, which is larger than δf_{ADC}. Therefore, in this case, the frequency resolution of the sine-cosine MFD is primarily limited by the noise level of the detection circuit.

Note that as the maximum measurable MFV speed γₘₐₓ increases, a higher ADC sampling rate Rₛ is required, and consequently the bandwidth B=Rₛ/2 of the electronic detection circuit needs to be increased, which will result in a decrease of SNRᵥ and eventually a degradation of the system's frequency resolution δfₙ. Let ρᵥ be the voltage noise density in Volt/\sqrt{Hz} of the detection electronic circuit, one arrives:

$${SNR}_{v} = \frac{{V}_{pp}}{{δ}_{v}} = \frac{{V}_{pp}}{{ρ}_{v} \sqrt{β}} = \frac{{V}_{pp}}{{ρ}_{v} \sqrt{{γ}_{max} τ}} \qquad ( 12 )$$

$$Δ {f}_{n} = \frac{1}{2 τ {SNR}_{v}} = \frac{{ρ}_{v}}{2 {V}_{pp}} \sqrt{\frac{{γ}_{max}}{τ}} \qquad ( 13 )$$

In the derivation, Eq. (8) is used. Eq. (13) represents the relationship between the frequency resolution and the measurable MFV rate of the sine-cosine MFD system for a given circuit noise density and signal amplitude.

In microwave circuits and devices, a delay by using a microwave coax cable dis too lossy to generate a sufficiently large delay T for the required resolution while still maintaining a sufficient power level of the delayed microwave signal. To address this technical issue, a photonic delay line (PhDL) is provided to enable a PhDL enabled sine-cosine MFD using discrete microwave and optical components, as shown in FIG. 2 where one of the two microwave signals after the microwave power splitter PS2 is directed to a photonic module for converting the microwave signal into an optical signal to undergo an optical delay in the PhDL and is then converted back into the microwave signal domain. The operating frequency range of the power splitters PS1 to PS4 is 1-16 GHZ. The 90° hybrid couplers have an operating frequency range of 3.8-14.6 GHZ, and the MVA has an attenuation range of 20 dB. The PhDL consists of a directly modulated laser (DML) with a wavelength of 1550 nm, an operating bandwidth of DC-18 GHZ, an output optical power of 10 dBm, a 1-km single-mode fiber coil, a high-speed photodetector (PD) with a responsivity of 0.85 A/W, and a low-noise amplifier (LNA) with an operating frequency range of 5-13 GHz and a gain of 37 dB. All interference signals output from the 90° HC are detected by the microwave detectors MD1-MD6 with an operating frequency range of 100 MHz-20 GHz. Six low-noise voltage amplifiers (VA) are used before the signals entering the data acquisition card (DAQ) for increasing the SNRs of the six signals. Each VA has a gain-bandwidth product of 40 MHz, and the 8-channel DAQ has a sampling rate of 80 kSa/s per channel and an effective resolution of 16 bits. The SUT used in the experiments includes Keysight N5183B signal source, the frequency-sweeping signal source in Keysight N5242A vector network analyzer, and a voltage-tunable VCO.

A continuous frequency-sweeping microwave source (Keysight N5242A) was evaluated using the sine-cosine MFD illustrated in FIG. 2. Due to the bandwidth limitations of the components in the MFD system, the frequency-sweeping range of the microwave source was set to extend from 5.7 to 12.7 GHZ. The scanning speed was set at 1 GHZ/s, with a scanning period of 14 seconds.

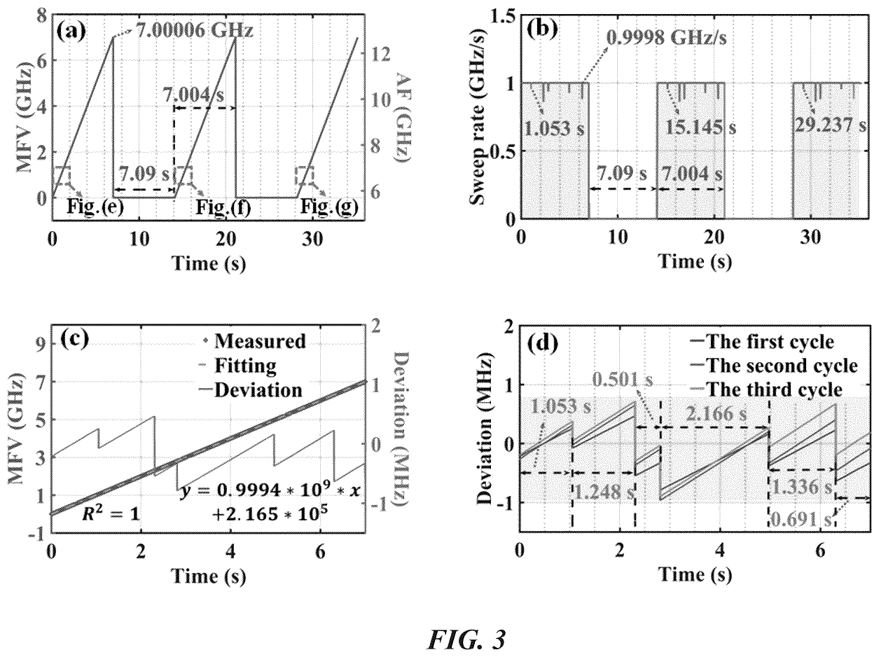

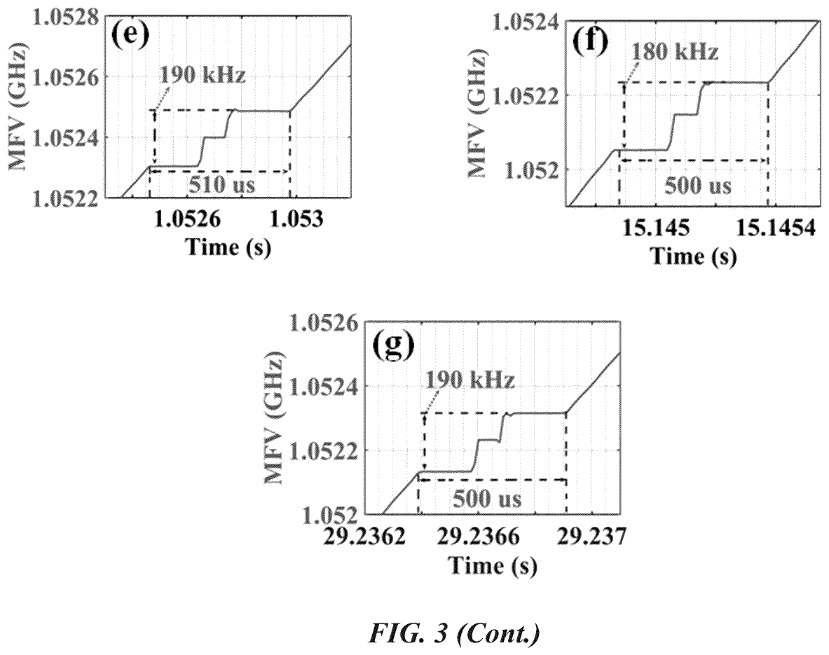

Referring now to FIG. 3, FIG. 3(a) of FIG. 3 presents the measured data of three frequency-sweeping cycles of the microwave source obtained via the sine-cosine MFD system. The total measured frequency span was determined to be 7.00006 GHZ, with a deviation of only 60 KHz from the preset value, representing a relative error of less than 10⁻⁵. The measured duration of a single frequency-sweeping cycle was 7.004 s, deviating by merely 4 ms from the configured setting. The right-hand vertical axis in the figure indicates the estimated results of the absolute frequency (AF) obtained with the UMZI in the MFD system, in agreement with the setting of the microwave source.

The frequency sweep rate or the MFV rate can be obtained by taking the time-derivative of the data in FIG. 3(a), with the results shown in FIG. 3(b) of FIG. 3. It can be observed that the sweep rate remains close to 1 GHz/s throughout the frequency sweeping process, highly consistent with the setting, however, with five sudden jumps at certain moments. The locations of these jumps are repeatable in the three cycles, indicating that they are not from the measurement noise. As will be shown next, they are actually from the frequency scanning discontinuities of the signal source, which are generally unnoticeable with other measurement methods.

FIG. 3(c) of FIG. 3 shows a linear fit of the first sweep cycle in FIG. 3(a), with the deviations from the linear fit plotted using the right-hand vertical axis. The nominal frequency scanning rate is determined to be 0.9994 GHz/s, with a goodness of fit of 1. The difference between the measured and setting sweep rate is found to be only 0.06%. It can be seen that there are totally 5 discontinuities of in the frequency sweep cycle, consistent with the number of sweep-rate jumps in FIG. 3(b), which is likely due to the auto-correction function of the signal source to periodically correct the frequency scan deviations from pre-determined values.

The deviations between the measured values and the linear fit for the three sweep cycles in FIG. 3(a) are shown in FIG. 3(d) in FIG. 3. The three curves in FIG. 3(d) show that the amounts of frequency scan deviations in the three cycles are different from one another, however, the auto-corrections in the three cycles occur at the same location in time, which is consistent with the jumps in FIG. 3(b).

FIGS. 3(e), (f), and (g) of FIG. 3 present the measured MFV results of the frequency sweeps when the first auto-correction occurs in each of the three cycles in FIG. 3(a), corresponding to the first scanning rate jump in FIG. 3(b). These results indicate that the duration for the first frequency correction is approximately 500 μs, with a frequency correction value of about 190 KHz. Such detailed MFV dynamics from a signal source may even never noticed with any other measurement methods.

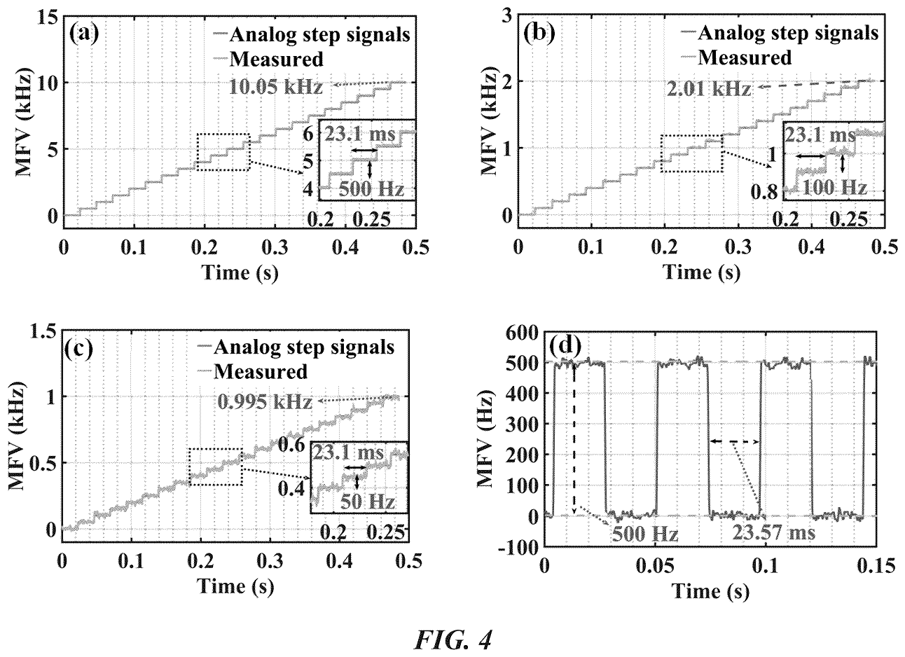

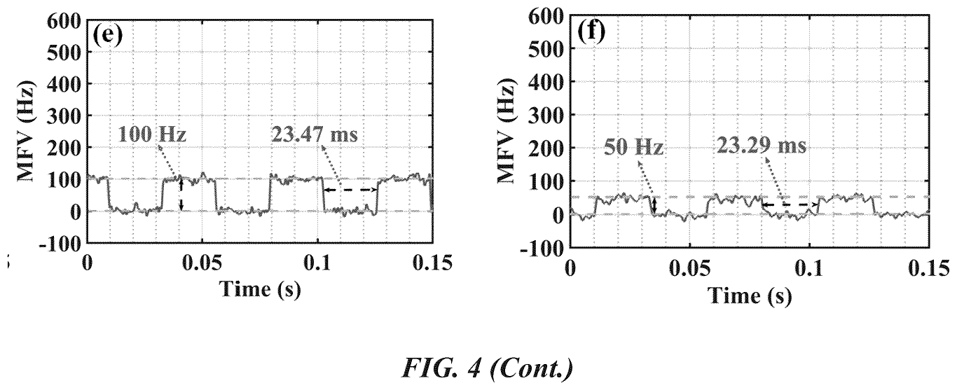

As discussed above, the frequency resolution of the sine-cosine MFD system primarily depends on three factors: the delay time t, the resolution of the DAQ card, and the noise level of the detection circuit. The analysis shows that, with a 1-km fiber-optic delay line (τ~5 μs) and 16-bit resolution DAQ card, the system's frequency resolution can reach 1.55 Hz when circuit noise is disregarded. When the noise of the electronic detection circuit is considered, the frequency resolution will be degraded. To find out the frequency resolution of our sine-cosine MFD system, two sets of experiments were performed using a signal generator (Keysight N5183B). In the first set of experiments, the signal generator is programmed to generate three different frequency scans with stepped frequency increments of 500 Hz, 100 Hz, and 50 Hz, respectively, and a dwell time of 20 ms for each step. All three scans start at 9 GHz, with ranges of 10 KHz, 2 kHz, and 1 kHz, respectively. The signal power was constantly maintained at 13 dBm throughout the experiments. FIGS. 4(a)-(c) show the measured frequency scans acquired by our sine-cosine MFD system, corresponding to step increments of 500 Hz, 100 Hz, and 50 Hz, respectively. In the figures, the orange curves represent the measurement results, whereas the light blue curves represent the numerically simulated step signals. As evidenced by the inset in each figure, our sine-cosine MFD system is capable of fully resolving the frequency increment down to 50 Hz. The measured dwell time of each step was found to be approximately 23.1 ms, deviating by 3.1 ms from the preset value of 20 ms, indicating that our system is also capable of detecting the minor discrepancy in the programmed and actual dwell time in the generated frequency scans.

To further validate the frequency resolution of our sine-cosine MFD system, tests were conducted on frequency-hopping signals generated by the signal source (Keysight N5183B). The starting frequency for all the frequency-hopping signals was set to 9 GHz, while the heights of the hops were configured to 500 Hz, 100 Hz, and 50 Hz, respectively. The dwell time for each frequency hop was maintained at 20 ms. FIG. 4 includes FIGS. 4(d)-(f) which present measurement results of the frequency hopping signal with hopping magnitudes of 500 Hz, 100 Hz, and 50 Hz, respectively. As shown in the figures in FIG. 4, our MFD system is capable of clearly resolving frequency-hopping heights down to 50 Hz. Like the case for frequency step measurement, the measured dwell time for each frequency hop was found to be approximately 23.4 ms, deviating from the 20 ms setting by 3.4 ms. Such a minor discrepancy of the signal generator can be clearly detected by our sine-cosine MFD system.

According to Eq. (8), the detection speed of our sine-cosine MFD system is primarily determined by the delay time t and the sampling rate of the DAQ card. For a sine-cosine MFD with 1 km fiber-optic delay, the theoretical maximum detectable frequency-sweeping speed is 8 GHz/s at a sampling rate of 80 kSa/s, determined by Nyquist sampling theorem. In practice, oversampling with at least eight data points per signal period is required [38, 39]. Consequently, the maximum detection speed of our sine-cosine MFD is calculated to be 2 GHz/s at the sampling rate of 80 kSa/s.

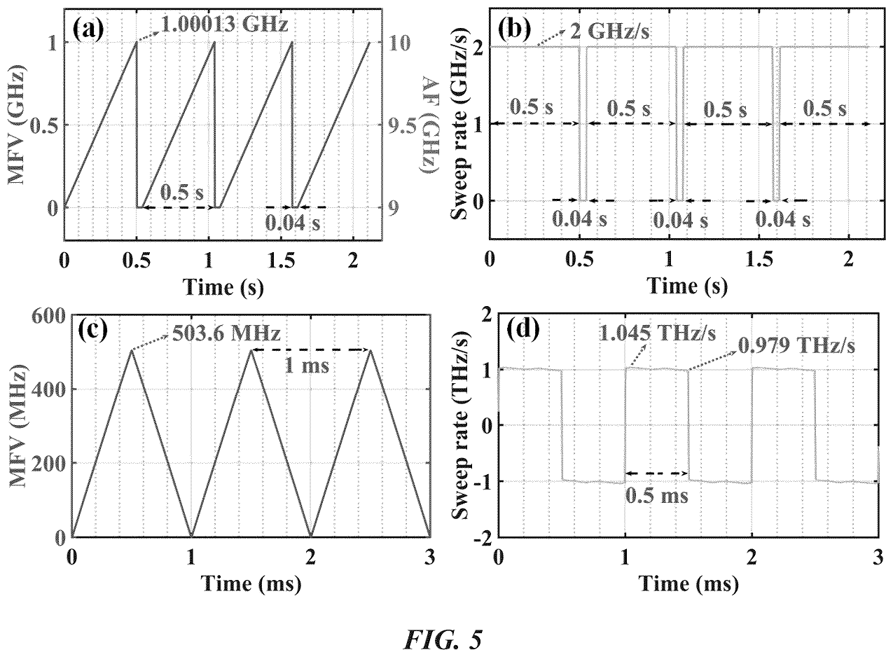

To verify this estimate, the frequency of a frequency-sweeping signal was measured at a sweeping speed of 2 GHz/s with a span of 1 GHz (9 to 10 GHZ), generated by a signal generator (Keysight N5242A). FIG. 5 includes FIGS. 5(a)-(d) with the frequency vs. time results shown in FIG. 5(a) and sweep speed results shown in FIG. 5(b), which is obtained by differentiating the data in FIG. 5(a) with respect to time. The measured results are highly consistent with the signal generator settings, including the waveform (saw-wave), the frequency span (1 GHZ), the frequency sweep period (0.5 s), the pause time between sweeps (0.04 s), and the sweep speed (2 GHz/s).

To verify that the sine-cosine MFD system can achieve faster detection speeds at higher sampling rates, a test was conducted by using an oscilloscope (Rohde & Schwarz RTB2004) with a sampling rate of 625 MSa/s to acquire the signals from the voltage amplifier. A voltage-controlled oscillator (VCO) is used to generate a high-speed frequency-sweeping signal by driving it with a voltage signal. The VCO has a sensitivity of approximately 0.3515 GHZ/V. When driven by a triangular wave signal with a frequency of 1 kHz and an amplitude of 1.45 Vpp, the VCO generates a frequency-swept signal at a rate of about 1.02 THz/s, with a span of 505 MHz from 7.895 GHz to 8.4 GHz measured with a spectrum analyzer. FIG. 5(c) of FIG. 5 presents the frequency variation of the VCO measured with our sine-cosine MFD, which shows a triangular wave with a period of 1 kHz and a span of 503.6 MHz, highly consistent with the applied VCO driving signal. By differentiating the data in FIG. 5(c) with respect to time, the frequency-sweeping rate of the VCO at different time points is obtained, as shown in FIG. 5(d) of FIG. 5. It can be observed that the frequency-sweeping of the VCO is not perfectly linear, with a maximum scanning speed of 1.045 THz/s and a minimum speed of 0.979 THz/s. To achieve even faster detection speeds, the microwave detector and the backend voltage amplifier need to have a larger detection bandwidth.

A comparative evaluation was conducted between our sine-cosine MFD system and a commercial short-time Fourier transform (ST-FFT) analyzer (Tektronix RSA306B). In terms of real-time analysis bandwidth, the ST-FFT analyzer exhibits a maximum measurement range of 40 MHz [40], whereas our sine-cosine MFD system operates over a significantly broader range, extending from 5.7 to 12.7 GHZ, which can be extended further with components of wider bandwidths.

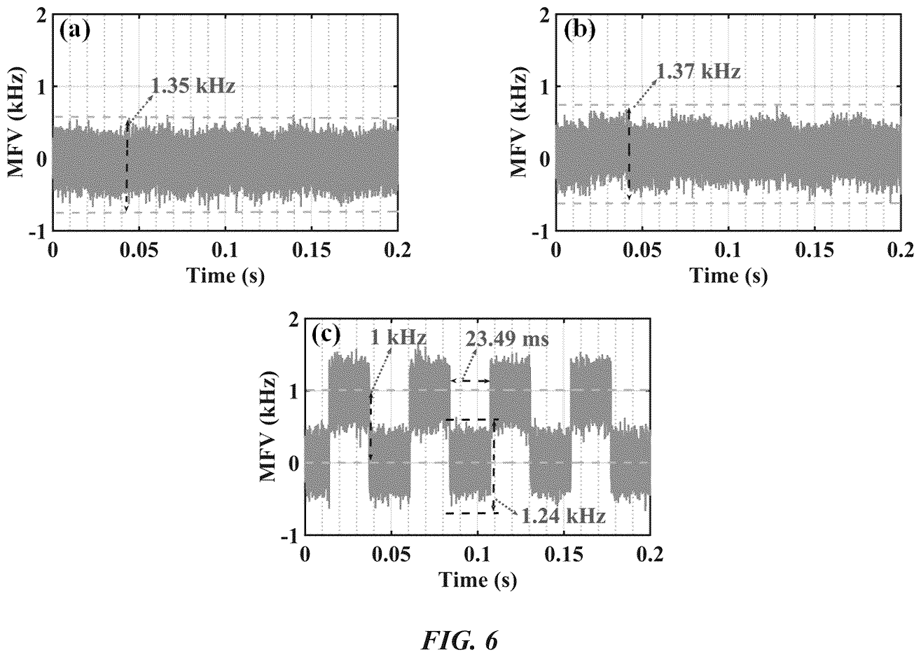

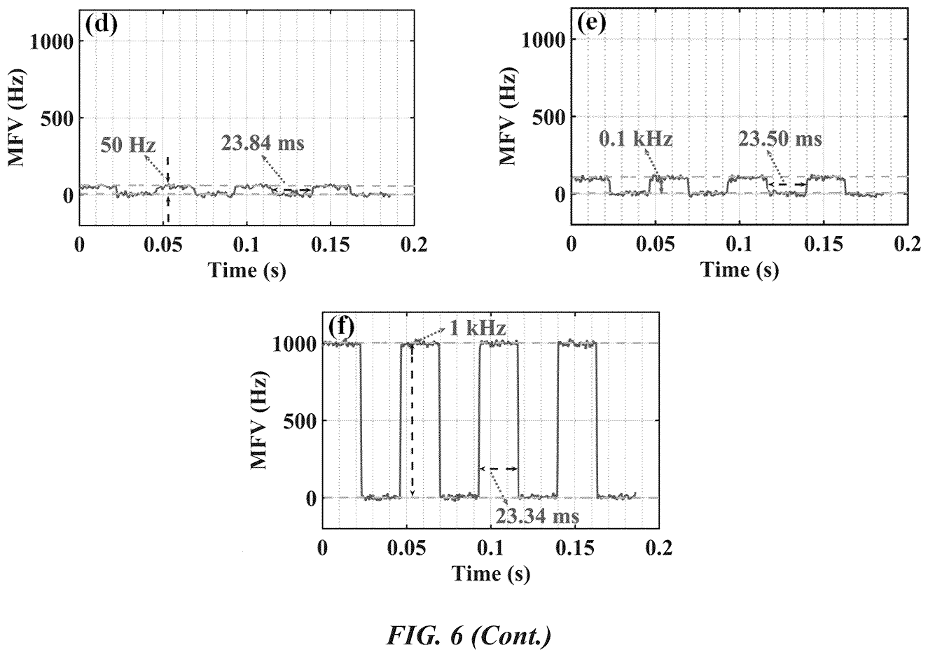

To assess the resolution, both systems were employed to measure frequency-hopping signals generated by a signal source (Keysight N5183B), with a fundamental frequency of 6 GHZ. The frequency-hopping magnitudes were chosen to be 50 Hz, 100 Hz, and 1 kHz. FIGS. 6(a)-6(c) of FIG. 6 present the MFV results obtained using the RSA306B USB Spectrum Analyzer by Tektronix which can operate within the frequency range of 9 KHz-6.2 GHz. When the frequency-hopping magnitude was at 50 Hz, the measured frequency changes were largely obscured by noise, as depicted in FIG. 6(a), with a noise magnitude of ±685 Hz. At a frequency hopping magnitude of 100 Hz, the measured frequency changes remained indistinguishable from the noise, as illustrated in FIG. 6(b). Finally, at a hopping magnitude of 1 kHz, the frequency changes could be barely discerned, as shown in FIG. 6(c). In contrast, our sine-cosine MFD system demonstrated superior resolution capabilities, clearly distinguishing all three frequency-hopping magnitudes down to 50 Hz, as evidenced in FIG. 6(d)-6(f).

It is well established that Doppler radar determines the velocity of a target by quantifying the frequency variation, known as the Doppler shift, between the transmitted signal and its corresponding reflected signal. Our sine-cosine MFD system is uniquely positioned to function as a high-resolution receiver for a passive Doppler radar, thereby enabling the detection of much slower moving targets.

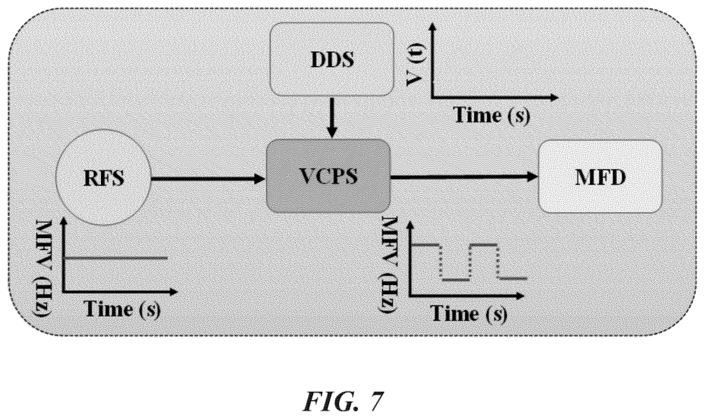

FIG. 7 shows an experimental setup that was used to conduct high-resolution Doppler shift measurements to demonstrate the capability of the disclosed sine-cosine MFD system. Doppler shifts can be synthesized by phase modulating a microwave signal source with a voltage-controlled phase shifter (VCPS) using driving signals generated by a direct digital synthesizer (DDS). The Doppler shift can be mathematically represented as:

$$df ( t ) = \frac{1}{2 π} \frac{d Φ ( t )}{dt} \qquad ( 14 )$$

where Φ(t) denotes the phase of the modulated microwave signal, which relates to the DDS modulation voltage V(t) by Φ(t)=β·V(t). Here, β represents the voltage-phase sensitivity of the VCPS, with a unit of radians per volt (rad/V). The generated Doppler shift can be rewritten as:

$$df ( t ) = \frac{1}{2 π} \frac{β \cdot d V ( t )}{dt} \qquad ( 15 )$$

It is evident that when V (t) is of a triangular waveform, the output from the VCPS represents a frequency-hopping signal, with its frequency hops between two values with time, corresponding to the up- and down-ramps of the modulation voltage. On the other hand, when V (t) is of a quadratic-waveform, the output is a periodic frequency-sweeping signal, with its frequency linearly sweeps with a positive and negative slopes, corresponding to the up- and down-ramps of the modulation voltage V (t).

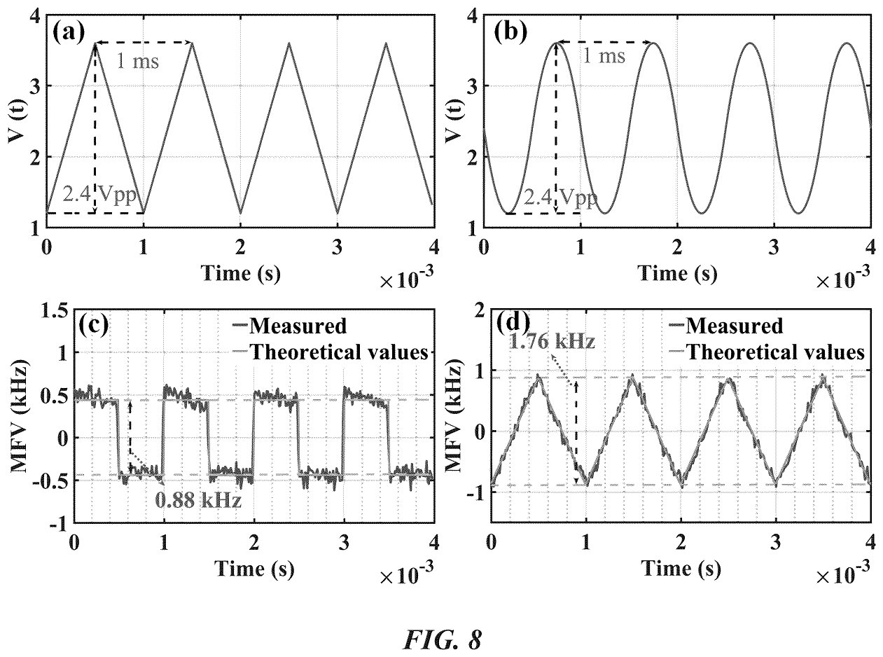

As depicted in FIG. 7, the microwave signal source (Keysight N5183B) generates a 9 GHz signal, which is subsequently fed into a VCPS with a phase sensitivity of 0.576 rad/V. FIG. 8 shows examples of measurements for showing Doppler shift generation and detection. The triangular and quadratic waveforms generated by the DDS with a fundamental frequency of 1 kHz are used to modulate the VCPS, as illustrated in FIGS. 8(a) and 8(b) in FIG. 8, respectively. Notably, the quadratic waveform over a single period is constructed by concatenating two quadratic functions with opposing orientations. The corresponding Doppler frequency shifts, as measured by the sine-cosine MFD system, are presented in FIGS. 8(c) and 8(d) in FIG. 8. In these figures, the blue curves denote the measurement results, while the green curves represent the theoretical calculations using Eq. (15). From FIG. 8(c) in FIG. 8, it is evident that when the modulation signal is a triangular wave, the theoretical calculation predicts a frequency-hopping signal with a hopping magnitude of 880 Hz. However, the measured results obtained via the MFD system exhibit a deviation from the theoretical prediction, which can be attributed to the inherent nonlinearity of the VCPS with respect to voltage. Similarly, FIG. 8(d) in FIG. 8 reveals that when the modulation signal is of a quadratic waveform, the measured Doppler frequency shift of the signal follows a triangular waveform with a variation range of 1.76 kHz, agreeing with the theoretical calculation. The nonlinearity of the VCPS also induces a slight deviation between the measured result and the theoretical calculation.

Note that the measurement resolution of Doppler shift using our sine-cosine MFD is also 50 Hz, the same as the frequency resolution obtained in FIG. 6, which corresponds to a velocity measurement resolution of 0.83 m/s (at fundamental frequency of 9 GHZ) of a moving object. The results above show our sine-cosine MFD system's potential as part of a passive radar system, with the advantages of strong concealment, low detectability, and low cost, compared with traditional active radar requiring a high power and low phase noise signal source [41].

To validate the capability of our sine-cosine MFD for characterizing fast frequency sweeps, we conducted an evaluation of a laboratory-constructed Fourier Domain Mode-Locked Optoelectronic Oscillator (FDML-OEO) [42]. The FDML-OEO is characterized by a center frequency of 9 GHZ, frequency scan range of 400 MHz, a scan period of 9.88 μs, and a frequency-sweeping rate of 40.49 THz/s. This sweeping rate considerably surpasses the maximum detectable tuning rate γₘₐₓ of the sine-cosine MFD system with a fiber-optic delay of 1 km, limited by the speeds of the detection electronics and the sampling rate DAQ card, as described by Eq. (8). To reduce the signal bandwidth from the I-Q interferometer, the fiber length in the PhDL is reduced to 50 m to accommodate the slow speeds of the microwave detectors, the voltages amplifiers, and the DAQ card.

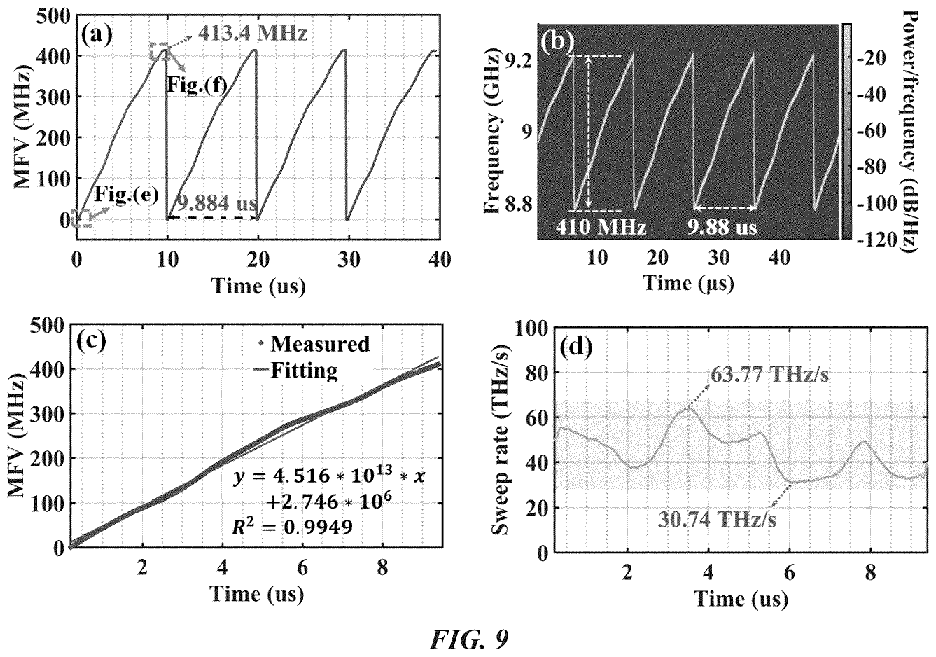

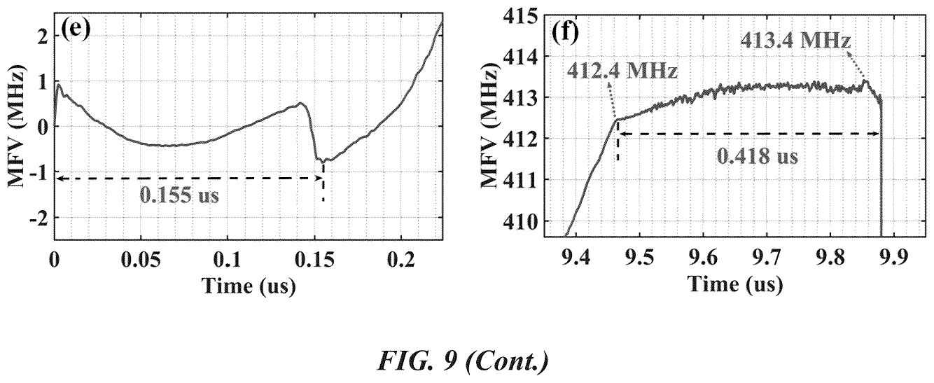

FIG. 9 shows examples of measurements indicating the characterization of rapid frequency sweeps from a FDML OEO. FIG. 9(a) of FIG. 9 presents the frequency variation of the frequency-swept signal generated by a FDML-OEO over four cycles, with a range of 413.4 MHz in a period of 9.884 μs, measured with our sine-cosine MFD, while FIG. 9(b) of FIG. 9 shows the same MFV measurement captured by a high-end commercial real-time spectrum analyzer (Keysight UXR0134A) based on ST-FFT for comparison. Although the two measurements agree well, the results from our sine-cosine MFD can reveal many more details of the frequency scan, as will be shown next.

FIG. 9(c) of FIG. 9 shows the linear fit of the middle section (marked red) of the frequency-sweep in the first cycle in FIG. 9(a), with a goodness of fit R²=0.9949. The residual frequency nonlinearity 1−R² can be calculated to be 5.1045*10⁻³, and the RMS (Root Mean Square) frequency error is 8.592 MHz [43]. FIG. 9(d) shows the frequency sweep rate, obtained by time-differentiating the measured MFV results in FIG. 9(c), with a nominal value of 41.84 THz/s and a maximum value of 63.77 THz/s.

FIG. 9(e) and FIG. 9(f) of FIG. 9 provide measurements for evaluating the detailed dynamics of the starting and ending segments of each frequency sweep cycle in FIG. 9(a), respectively. In FIG. 9(e), a time delay of 0.155 μs is observed in the FDML-OEO sweep output, while FIG. 9(f) shows that the frequency at the end of each sweep cycle persists for 0.418 μs. These details cannot be observed with ST-FFT measurements.

In summary, this patent document provides an experimentally validated novel technique for real-time microwave frequency variation measurement enabled by a microwave photonic delay line. Leveraging the sine-cosine encoder approach commonly employed in motor rotation detection and control, this technique achieves unprecedented resolution and speed, marking a significant leap forward in the field. This novel technique applies a robust demodulation formula and an effective calibration algorithm to address device imperfections, ensuring high accuracy over a wide frequency range at a low system cost. Our conducted measurements, utilizing a 1-km fiber delay line, showcased measurement capabilities across a broad frequency range of 5.7-12.7 GHZ, with an impressive scanning speed of 1 THz/s and a resolution of 50 Hz, surpassing previous microwave photonic methods by over four orders of magnitude. The primary limitations in range, speed, and resolution stem from the bandwidth of microwave components, as well as the speed and noise of the backend detection circuit, all of which can be significantly improved. Comparisons between our sine-cosine MFD and a commercial short-time Fourier transform analyzer (Tektronix RSA306B) revealed the superior performance of the sine-cosine MFD in both measurement resolution, speed and range, positioning it as a state-of-the-art tool for high-precision microwave frequency measurements. The resolution of our sine-cosine MFD can be further improved by using PhDL with longer fiber length while the operation frequency can be extended up to 220 GHz with thin film lithium niobate based PhDL [44, 45]

In practical applications, the disclosed technology can be used to provide a sine-cosine MFD to analyze Doppler-shift signals and frequency-swept microwave signals generated by an FDML OEO. In our conducted measurements, the measured Doppler-shift signals were in excellent agreement with theoretical predictions, enabling the real-time detection of low-speed moving targets with velocities as low as 0.83 m/s, and promising to play a crucial role in integrated sensing and communication (ISAC) systems [46, 47] for sensitive motion sensing. Additionally, the sine-cosine MFD revealed ultrafine details of frequency sweeps generated by the FDML OEO, which were not observable with high-end ST-FFT analyzers (Keysight UXR0134A), and accurately determined frequency-sweeping speeds up to 63.77 THz/s with a PhDL of 50 m. These results underscore the versatility and superior performance of the sine-cosine MFD, establishing it as an invaluable asset for advanced microwave measurement and sensing tasks.

While this patent document contains many specifics, these should not be construed as limitations on the scope of any disclosed technology or of what may be claimed, but rather as descriptions of features that may be specific to particular embodiments of particular disclosed technology. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

### REFERENCES

1. X. Zou, B. Lu, W. Pan, et al., “Photonics for microwave measurements,” Laser Photonics Rev. 10, 711-734 (2016).
2. A. Akan and O. Karabiber Cura, “Time-frequency signal processing: Today and future,” Digit. Signal Processing 119 (2021).
3. J.-K. Wu, K, Gao, W. Yue, et al., “A way to determine the optimum detection frequency for microwave sensing,” Measurement 202 (2022).
4. M. T. Hunter, A. G. Kourtellis, C. D. Ziomek, et al., “Fundamentals of modern spectral analysis,” 14, 12-16 (2011).
5. C. J. U. P. H. Leon, “Time-frequency analysis: theory and applications,” (1995).
6. S. Qian and D. J. I. s. p. m. Chen, “Joint time-frequency analysis,” 16, 52-67 (1999).
7. R. B. Pachori, Time-frequency analysis techniques and their applications (CRC Press, 2023).
8. C. Mateo and J. A. Talavera, “Short-time Fourier transform with the window size fixed in the frequency domain,” Digit. Signal Processing 77, 13-21 (2018).
9. J. Li, S. N. Fu, X. Z. Xie, et al., “Low-Latency Short-Time Fourier Transform of Microwave Photonics Processing,” J. Lightwave Technol. 41, 6149-6156 (2023).
10. L. A. Bui, “Recent advances in microwave photonics instantaneous frequency measurements,” Prog. in Quantum Electron. 69 (2020).

11 J. Zhou, S. Fu, S. Aditya, et al., “Instantaneous Microwave Frequency Measurement Using Photonic Technique,” IEEE Photonics Technol. Lett. 21, 1069-1071 (2009).
12. L. V. Nguyen, “Microwave frequency measurement utilising frequency to time mapping,” in 2008 International Topical Meeting on Microwave Photonics jointly held with the 2008 Asia-Pacific Microwave Photonics Conference, (IEEE, 2008), 330-332.
13. L. A. Bui, M.-D. Pelusi, T. D. Vo, et al., “Instantaneous frequency measurement system using optical mixing in highly nonlinear fiber,” 17, 22983-22991 (2009).
14. Y. C. Xiao, J. Guo, K. Wu, et al., “Multiple microwave frequencies measurement based on stimulated Brillouin scattering with improved measurement range,” Opt. Express 21 (2013).
15. J. Li, L. Pei, T. Ning, et al., “Measurement of Instantaneous Microwave Frequency by Optical Power Monitoring Based on Polarization Interference,” J. Lightwave Technol. 38, 2285-2291 (2020).
16 Y. Zhu, B. L. Wu, M. G. Wang, et al., “Instantaneous Frequency Measurement Using Optical Power Monitoring Based on a DP-DPMZM,” in 2021 IEEE 6th Optoelectronics Global Conference (OGC), (2021), pp. 132-134.
17. Z. Zhao, K. Zhu, L. Lu, et al., “Instantaneous microwave frequency measurement using few-mode fiber-based microwave photonic filters,” Opt. Express 28 (2020).
18. D. F. Shi, G. Y. Li, Z. Y. Jia, et al., “Accuracy enhanced microwave frequency measurement based on the machine learning technique,” Opt. Express 29 (2021).
19. S. Wang, G. Wu, Y. Sun, et al., “Photonic compressive receiver for multiple microwave frequency measurement,” Opt. Express 27 (2019).
20. Y. Huang, J. J. Guo, L. Z. Jiang, et al., “Photonics-assisted two-step microwave frequency measurement based on frequency-to-time mapping,” Opt. and Quantum Electron. 55 (2023).
21 X. Y. Chen, W. H. Dong, Z. X. Kong, et al., “Precise Multiple Frequency Identification Based on Frequency-to-Time Mapping and Cross-Correlation,” J. Lightwave Technol. 41, 5895-5901 (2023).
22 M. Li and J. Yao, “All-Optical Short-Time Fourier Transform Based on a Temporal Pulse-Shaping System Incorporating an Array of Cascaded Linearly Chirped Fiber Bragg Gratings,” IEEE Photonics Technol. Lett. 23, 1439-1441 (2011).
23. S. R. Konatham, R. Maram, L. R. Cortes, et al., “Real-time gap-free dynamic waveform spectral analysis with nanosecond resolutions through analog signal processing,” Nat. Commun. 11 (2020).
24. X. Xie, J. Li, F. Yin, et al., “STFT Based on Bandwidth-Scaled Microwave Photonics,” J. Lightwave Technol. 39, 1680-1687 (2021).
25. J. Azaña, X. Zhu, C. Rowe, et al., “Optical Time-Mapped Spectrograms (II): Fractional Talbot Designs,” J. Lightwave Technol. 41, 5284-5295 (2023).
26. Z. Lin, et al., “Wideband and low-error microwave frequency measurement using degenerate four-wave mixing-based nonlinear interferometer,” Optics Letters 44 (2019).
27. H. Emami, M. Ashourian, and M. Ebnali-Heidari, “Dynamically Reconfigurable All Optical Frequency Measurement System,” J. Lightwave Technol. 32, 4796-4802 (2014).
28. M. Ebnali-Heidari, A. Ebnali-Heidari, and H. Emami, “Utilization of slow light enhancement of four-wave mixing within a silicon photonic crystal for microwave frequency measurement purposes,” J. Opt. Soc. Am. B 38 (2021).
29 W. Jiao, K. You, and J. Sun, “Multiple Microwave Frequency Measurement With Improved Resolution Based on Stimulated Brillouin Scattering and Nonlinear Fitting,” IEEE Photonics J. 11, 1-12 (2019).
30. J. Liu, T. Shi, and Y. Chen, “High-Accuracy Multiple Microwave Frequency Measurement With Two-Step Accuracy Improvement Based on Stimulated Brillouin Scattering and Frequency-to-Time Mapping,” J. Lightwave Technol. 39, 2023-2032 (2021).
31. P. Zuo, D. Ma, and Y. Chen, “Short-Time Fourier Transform Based on Stimulated Brillouin Scattering,” J. Lightwave Technol. 40, 5052-5061 (2022).
32 P. Zuo, D. Ma, X. Li, et al., “Improving the Accuracy and Resolution of Filter- and Frequency-to-Time Mapping-Based Time and Frequency Acquisition Methods by Broadening the Filter Bandwidth,” IEEE Trans. Microwave Theory Tech. 71, 3668-3677 (2023).
33. X. Li, T. Shi, D. Ma, et al., “Channelized Analog Microwave Short-Time Fourier Transform in the Optical Domain,” IEEE Trans. Microwave Theory Tech. 72, 3210-3220 (2024).
34. X. S. Yao and X. Ma, “Sine-Cosine Techniques for Detecting Fast Optical Frequency Variations With Ultra-High Resolution,” J. Lightwave Technol. 41, 1041-1053 (2023).
35. X. Ma and X. S. Yao, “Single-Frequency Lasers' Linewidths Elegantly Characterized with Sigmoid Functions of Observation Time,” J. Lightwave Technol. 42, 4569-4584 (2024).
36. X. S. Yao, Y. L. Yang, X. S. Ma, et al., “On-chip real-time detection of optical frequency variations with ultrahigh resolution using the sine-cosine encoder approach,” Nat. Commun. (to be published).
37. Y. Lee, S. H. Kim, S.-H. Lee, et al., “Encoder Calibration Method for High Precision Servo Systems With a Sinusoidal Encoder,” IEEE Trans. Ind. Electron. 69, 752-762 (2022).
38. M. Hao, F. Han, and Y. Wang, et al., “Comments on nyquist rate in engineering application,” in 2010 International Conference On Computer Design and Applications, (IEEE, 2010), V3-5-V3-7.
39. S. Das, N. Mohanty, and A. Singh, “Is the Nyquist Rate Enough?,” in 2008 The Third International Conference on Digital Telecommunications (icdt 2008), (2008), pp. 27-32.
40. RSA306B-USB-Real-Time-Spectrum-Analyzer-Datasheet-ZH-CN-37C603758, Tektronix, Beaverton, O. R, USA.
41 H. Kuschel, et al., “Tutorial: Passive radar tutorial,” IEEE Aerospace and Electronic Systems Magazine 34, 2-19 (2019).
42. P. Hao, Z. Y. Dong, D. X. Han, et al., “Simultaneous Dual-Band Frequency-Agile Microwave Signal Generation With a Dual Loop Fourier Domain Mode Locked Optoelectronic Oscillator,” J. Lightwave Technol. 42, 7710-7716 (2024).
43. X. Zhang, J. Pouls, and M. C. Wu, “Laser frequency sweep linearization by iterative learning pre-distortion for FMCW LiDAR,” Opt. Express 27 (2019).
44. R. Ma, Z. J. Huang, W. Ke, et al., “Widely tunable Ka-band optoelectronic oscillator integrated on thin film lithium niobate platform,” APL Photonics 9 (2024).
45. H. Liu, Y. T. He, B. Xiong, et al., “Ultra-High-Efficiency Dual-Band Thin-Film Lithium Niobate Modulator Incorporating Low-k Underfill with 220 GHz Extrapolated Bandwidth for 390 Gbit/s PAM8 Transmission,” (2024).
46. S. H. Lu, F. Liu, Y. X. Li, et al., “Integrated Sensing and Communications: Recent Advances and Ten Open Challenges,” IEEE Internet Things J. 11, 19094-19120 (2024).
47. L. Wang, X. Wang, and S. Pan, “Microwave Photonics Empowered Integrated Sensing and Communication for 6G,” IEEE Trans. Microwave Theory Tech. 1-21 (2025).

What is claimed is what is described and/or illustrated, including:

1. A microwave-photonic hybrid device for measuring a variation of a microwave signal frequency, comprising:
a first microwave power splitter to receive and split an input microwave signal at an input microwave frequency into a first input microwave signal and a second input microwave signal;
a photonic module coupled to receive the first input microwave signal from the first microwave power splitter and structured to include: a light source operable to generate light that is modulated by the first input microwave signal to produce a modulated optical signal carrying the first input microwave signal, an optical delay device coupled to receive the modulated optical signal carrying the first input microwave signal and to cause an optical delay in the modulated optical signal, and an optical detector coupled to the optical delay device to convert the modulated optical signal into a photonically delayed first input microwave signal;
a first microwave 90-degree hybrid coupler coupled to receive the photonically delayed first input microwave signal from the optical detector of the photonic module to split the received photonically delayed first input microwave signal into a first photonically delayed microwave signal and a second photonically delayed microwave signal that exhibits a 90-degree phase shift relative to a phase of the first photonically delayed microwave signal;
a second microwave power splitter coupled to receive and split the second input microwave signal from the first microwave power splitter into a third microwave signal and a fourth microwave signal that exhibits a 90-degree phase shift relative to a phase of the third microwave signal;
a second microwave 90-degree hybrid coupler coupled to receive the first photonically delayed microwave signal from the first microwave 90-degree hybrid coupler and the third microwave signal from the second microwave power splitter to form a first microwave Mach-Zehnder interferometer to cause interference between the first photonically delayed microwave signal and the third microwave signal to produce first and second microwave Mach-Zehnder interferometer output signals;
a first microwave detector coupled to receive the first microwave Mach-Zehnder interferometer output signal to produce a first detector output signal;
a second microwave detector coupled to receive the second microwave Mach-Zehnder interferometer output signal to produce a second detector output signal;
a third microwave 90-degree hybrid coupler coupled to receive the second photonically delayed microwave signal from the first microwave 90-degree hybrid coupler and the fourth microwave signal from the second microwave power splitter to form a second microwave Mach-Zehnder interferometer to cause interference between the second photonically delayed microwave signal and the fourth microwave signal to produce third and fourth microwave Mach-Zehnder interferometer output signals;
a third microwave detector coupled to receive the third microwave Mach-Zehnder interferometer output signal to produce a third detector output signal;
a fourth microwave detector coupled to receive the fourth microwave Mach-Zehnder interferometer output signal to produce a fourth detector output signal; and
a processing module coupled to receive information of the first, second, third and fourth detector output signals and operable to process the first, second, third and fourth detector signals to determine a change in the input microwave frequency of the input microwave signal.

2. The microwave-photonic hybrid device as in claim 1, wherein the optical delay device in the photonic module includes an optical fiber line.

3. The microwave-photonic hybrid device as in claim 1, wherein:
the second microwave 90-degree hybrid coupler is configured as the first microwave Mach-Zehnder interferometer to cause each of the first and second microwave Mach-Zehnder interferometer output signals to vary as a sine function of the input microwave frequency of the input microwave signal; and
the third microwave 90-degree hybrid coupler is configured as the second microwave Mach-Zehnder interferometer to cause each of the third and fourth microwave Mach-Zehnder interferometer output signals to vary as a cosine function of the input microwave frequency of the input microwave signal.

4. The microwave-photonic hybrid device as in claim 3, further comprising:
a third microwave power splitter coupled to receive a portion of the input microwave signal at the input microwave frequency to split the received portion into a fifth microwave signal and a sixth microwave signal;
a microwave delay device coupled to receive the fifth microwave signal to cause a delay in the fifth microwave signal;
a fourth microwave 90-degree hybrid coupler coupled to receive the fifth microwave signal with the delay from the microwave delay device and the sixth microwave signal from the third microwave power splitter to form a third microwave Mach-Zehnder interferometer to cause interference between the fifth microwave signal with the delay and the sixth microwave signal to produce fifth and sixth microwave Mach-Zehnder interferometer output signals;
a fifth microwave detector coupled to receive the fifth microwave Mach-Zehnder interferometer output signal to produce a fifth detector output signal; and
a sixth microwave detector coupled to receive the sixth microwave Mach-Zehnder interferometer output signal to produce a sixth detector output signal,
wherein the processing module is further coupled to receive and process the fifth and sixth detector output signals to measure an absolute value of the input microwave frequency of the input microwave signal in addition to the change in the input microwave frequency.

5. The microwave-photonic hybrid device as in claim 1, further comprising:
a third microwave power splitter coupled to receive a portion of the input microwave signal at the input microwave frequency to split the received portion into a fifth microwave signal and a sixth microwave signal;
a microwave delay device coupled to receive the fifth microwave signal to cause a delay in the fifth microwave signal;
a fourth microwave 90-degree hybrid coupler coupled to receive the fifth microwave signal with the delay from the microwave delay device and the sixth microwave signal from the third microwave power splitter to form a third microwave Mach-Zehnder interferometer to cause interference between the fifth microwave signal with the delay and the sixth microwave signal to produce fifth and sixth microwave Mach-Zehnder interferometer output signals;
a fifth microwave detector coupled to receive the fifth microwave Mach-Zehnder interferometer output signal to produce a fifth detector output signal; and
a sixth microwave detector coupled to receive the sixth microwave Mach-Zehnder interferometer output signal to produce a sixth detector output signal,
wherein the processing module is further coupled to receive and process the fifth and sixth detector output signals to measure an absolute value of the input microwave frequency of the input microwave signal in addition to the change in the input microwave frequency.

6. The microwave-photonic hybrid device as in claim 5, wherein the optical delay device in the photonic module includes an optical fiber line.

7. The microwave-photonic hybrid device as in claim 1, wherein the light source in the photonic module includes a diode laser that generates laser light that is modulated by the first input microwave signal to produce the modulated optical signal carrying the first input microwave signal.

8. A device for measuring a microwave or radio frequency signal, comprising:
first and second microwave or radio frequency (RF) interferometers coupled to form two arms of a microwave or radio frequency measurement device in which the first microwave or RF interferometer is configured to a delay imbalance of one quarter wavelength longer than a delay of the second microwave or RF interferometer to produce an additional phase difference between the two arms;
signal detectors coupled to detect outputs of the first and second microwave or RF interferometers to produce two complementary interference signals where a difference between the two complementary interference signals of the first microwave or RF interferometer is a sine function of the microwave or RF frequency and a difference between the two complementary interference signals of the second microwave or RF interferometer is proportional to a cosine function of the microwave or RF frequency; and
a photonic module structured to include: a light source operable to generate light that is modulated by an input microwave or RF signal to produce a modulated optical signal, an optical delay device coupled to receive the modulated optical signal and to cause an optical delay in the modulated optical signal, and an optical detector coupled to the optical delay device to convert the modulated optical signal into a photonically delayed input microwave signal, wherein the photic module is coupled to the first and second microwave or RF interferometers which operate on the photonically delayed input microwave signal; and
a processing module coupled to receive information of detector output signals of the signal detectors and operable to process the received detector signals to determine a change in the input microwave frequency of the input microwave signal.

9. The device as in claim 8, wherein the optical delay device in the photonic module includes an optical fiber line.

10. The device as in claim 8, wherein the light source in the photonic module includes a diode laser that generates laser light that is modulated to produce the modulated optical signal.
